(19) United States
(12) Patent Application Publication
(10) Pub. No.: US 2017/0236880 A1
(43) Pub. Date: Aug. 17, 2017

(54) ELECTRO-OPTICAL DEVICE AND ELECTRONIC APPARATUS

(71) Applicant: SEIKO EPSON CORPORATION, Tokyo (JP)

(72) Inventor: Naotaka KUBOTA, Chino-shi (JP)

(73) Assignee: SEIKO EPSON CORPORATION, Tokyo (JP)

(21) Appl. No.: 15/423,150

(22) Filed: Feb. 2, 2017

(30) Foreign Application Priority Data
Feb. 15, 2016 (JP) 2016-026414

(51) Int. Cl. H01L 27/32; H01L 51/52; G02B 5/20

(52) U.S. Cl. CPC H01L 27/3206; G02B 5/201; H01L 51/5265; H01L 27/322

(57) ABSTRACT

An electro-optical device includes a substrate; a first organic EL element that is formed in a first sub pixel on the substrate; a second organic EL element that is formed in a second sub pixel adjacent to the first sub pixel on the substrate; a sealing part that is formed to cover the first organic EL element and the second organic EL element; a first coloring layer that is formed in the first sub pixel on the sealing part; a second coloring layer that is formed in the second sub pixel on the sealing part; and a convex portion that has light transmission properties and is formed between the first sub pixel and the second sub pixel on the sealing part, in which the first coloring layer and the second coloring layer are disposed to overlap each other at an upper surface portion of the convex portion.

### BACKGROUND

1. Technical Field

The present invention relates to an electro-optical device including an organic electroluminescence (EL) element and an electronic apparatus.

2. Related Art

Since an organic EL element as a luminescence element is able to be miniaturized and thinner than a light emitting diode (LED), applications to a microdisplay such as a head mount display (HMD), an electronic view finder (EVF), and the like have been noted. As means for realizing a color display in such a microdisplay, a configuration combining the organic EL element from which white light luminance can be obtained and a color filter has been proposed (see, for example, JP-A-2014-089804).

In an electro-optical device (organic EL device) of JP-A-2014-089804, a sealing part is formed to cover a plurality of organic EL elements which are disposed on a substrate and the color filter that is configured to have coloring layers of red (R), green (G), and blue (B) is formed on the sealing part using a photolithography method. The coloring layers constituting the color filter are divided by a convex portion having light transmission properties.

### SUMMARY

In such an organic EL device, color purity of each of light of red color, green color, and blue color is increased and a high-quality display is obtained by light generated from the organic EL element in each of sub pixels of red color, green color, and blue color passing through the coloring layers corresponding to a wavelength of each of the colors. However, when oblique light which is generated from the organic EL element of one sub pixel of the sub pixels adjacent to each other passes between the sub pixels to be visible from an oblique direction, it is apprehended that color mixture occurs between the sub pixels adjacent to each other. Then, a viewing angle at which a color display of which a display unit is each of sub pixels of red, green, and blue can be visible within an originally intended color range is narrowed.

The invention has been realized in the following aspects or application examples.

### Application Example 1

According to this application example, there is provided an electro-optical device including: a substrate; a first organic EL element that is formed in a first pixel on the substrate; a second organic EL element that is formed in a second pixel adjacent to the first pixel on the substrate; a sealing part that is formed to cover the first organic EL element and the second organic EL element; a first coloring layer that is formed in the first pixel on the sealing part; a second coloring layer that is formed in the second pixel on the sealing part; and a convex portion that has light transmission properties and is formed between the first pixel and the second pixel on the sealing part, in which the first coloring layer and the second coloring layer are disposed to overlap each other at an upper surface portion of the convex portion.

According to a configuration of the electro-optical device of the application example, the convex portion having light transmission properties is formed between the first pixel in which the first coloring layer is formed and the second pixel in which the second coloring layer is formed and the first coloring layer and the second coloring layer are disposed to overlap each other in the upper surface portion of the convex portion. Therefore, for example, oblique light emitted from the first organic EL element to between the first pixel and the second pixel passes through both of the first coloring layer and the second coloring layer after passing through the convex portion. Thus, the amount of transmission of the oblique light emitted from the first organic EL element to between the first pixel and the second pixel is suppressed as compared with a case where the oblique light passes through only the first coloring layer. Accordingly, since the color mixture is less likely to occur between the first pixel and the second pixel, the electro-optical device obtaining the color display with high quality in the more wide viewing angle can be provided.

### Application Example 2

In the electro-optical device according to the application example, it is preferable that light emitted from the first organic EL element to the sealing part side be within a first wavelength range, light emitted from the second organic EL element to the sealing part side be within a second wavelength range different from the first wavelength range, the first coloring layer have transmittance of equal to or more than 75% with respect to light within the first wavelength range and transmittance of equal to or less than 25% with respect to light with a predetermined wavelength which is closer to the second wavelength range side than to the first wavelength range, and the second coloring layer have transmittance of equal to or more than 75% with respect to light within the second wavelength range and transmittance of equal to or less than 25% with respect to light with a predetermined wavelength which is closer to the first wavelength range side than to the second wavelength range.

According to the configuration of the application example, the first coloring layer disposed in the first pixel transmits light within the first wavelength range emitted from the sealing part side of the first organic EL element by equal to or more than 75%, but, transmits light with a predetermined wavelength which is closer to the second wavelength range side than to the first wavelength range only by equal to less than 25%. Also, the second coloring layer disposed in the second pixel transmits light within the second wavelength range emitted from the sealing part side of the second organic EL element by equal to or more than 75%, but, transmits light with a predetermined wavelength which is closer to the first wavelength range side than to the second wavelength range only by equal to or less than 25%. Therefore, the color purity of light emitted from each of the first pixel and the second pixel is increased. Also, since the amount of transmission of the oblique light emitted from the first organic EL element to between the first pixel and the second pixel is suppressed by the second coloring layer and the amount of transmission of the oblique light emitted from the second organic EL element to between the first pixel and the second pixel is suppressed by the first coloring layer, the color mixture is suppressed between the first pixel and the second pixel. Accordingly, the electro-optical device obtaining the color display with high quality in the wide color range and in the wide viewing angle can be provided.

### Application Example 3

In the electro-optical device according to the application example, it is preferable that a width of a part in which the first coloring layer and the second coloring layer overlap each other in the upper surface portion of the convex portion be 15% to 75% of a width of a lower surface portion of the convex portion.

According to the configuration of the application example, since the width of the part in which the first coloring layer and the second coloring layer overlap each other is equal to or more than 15% of the width of the lower surface portion of the convex portion, each of the oblique light emitted from the first organic EL element or the second organic EL element to between the first pixel and the second pixel is likely to pass through both of the first coloring layer and the second coloring layer. Also, since the width of the part in which the first coloring layer and the second coloring layer overlap each other is equal to or less than 75% of the width of the lower surface portion of the convex portion, the first coloring layer and the second coloring layer are prevented from protruding to the adjacent pixels.

### Application Example 4

In the electro-optical device according to the application example, it is preferable that the first coloring layer and the second coloring layer are disposed to cover at least a part of the upper surface portion of the convex portion.

### Application Example 5

There is provided an electronic apparatus including the electro-optical device described in the application example.

According to configurations of the application example, it is possible to provide the electronic apparatus having the excellent display quality.

### BRIEF DESCRIPTION OF THE DRAWINGS

The invention will be described with reference to the accompanying drawings, wherein like numbers reference like elements.

FIG. 1 is a schematic plan view illustrating a configuration of an organic EL device according to a first embodiment.

FIG. 2 is an equivalent circuit diagram illustrating an electrical configuration of the organic EL device according to the first embodiment.

FIG. 3 is a schematic plan view illustrating disposition of an organic EL element and a color filter in a sub pixel.

FIG. 4A is a schematic cross-sectional view illustrating a configuration of the sub pixel taken along line IVA-IVA in FIG. 3.

FIG. 4B is a schematic cross-sectional view illustrating the enlarged color filter in FIG. 4A.

FIG. 5 is a diagram illustrating viewing angle characteristics of an organic EL device according to the first embodiment.

FIG. 6 is a table illustrating spectrum characteristics of the color filter according to the first embodiment.

FIG. 7 is a diagram illustrating one example of the spectrum characteristics of the color filter.

FIG. 8 is a diagram illustrating another example of the spectrum characteristics of the color filter.

FIG. 9 is a diagram illustrating another example of the spectrum characteristics of the color filter.

FIG. 10A is a diagram illustrating viewing angle characteristics of an example.

FIG. 10B is a diagram illustrating the viewing angle characteristics of the example.

FIG. 11 is a schematic view illustrating a configuration of a head mount display as an electronic apparatus according to a second embodiment.

FIG. 12 is a diagram illustrating viewing angle characteristics of an organic EL device according to a comparative example.

### DESCRIPTION OF EXEMPLARY EMBODIMENTS

Hereinafter, embodiments according to the invention will be described with reference to drawings. Furthermore, the drawings used may be appropriately enlarged or reduced in order to display parts to be described in a recognizable state.

Furthermore, in the following embodiments, meaning referred to as “on a substrate” includes, unless specifically noted, a case in which an element is disposed to be in contact with the substrate, a case in which the element is disposed on the substrate via another construct, and a case in which a part of the element is disposed in contact on the substrate and the other part is disposed on the substrate via other construct.

### First Embodiment

### Electro-Optical Device

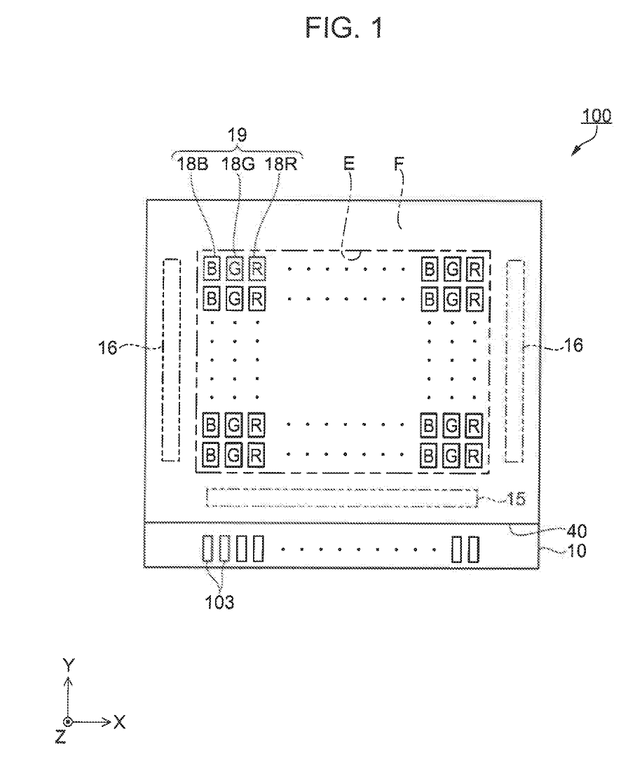

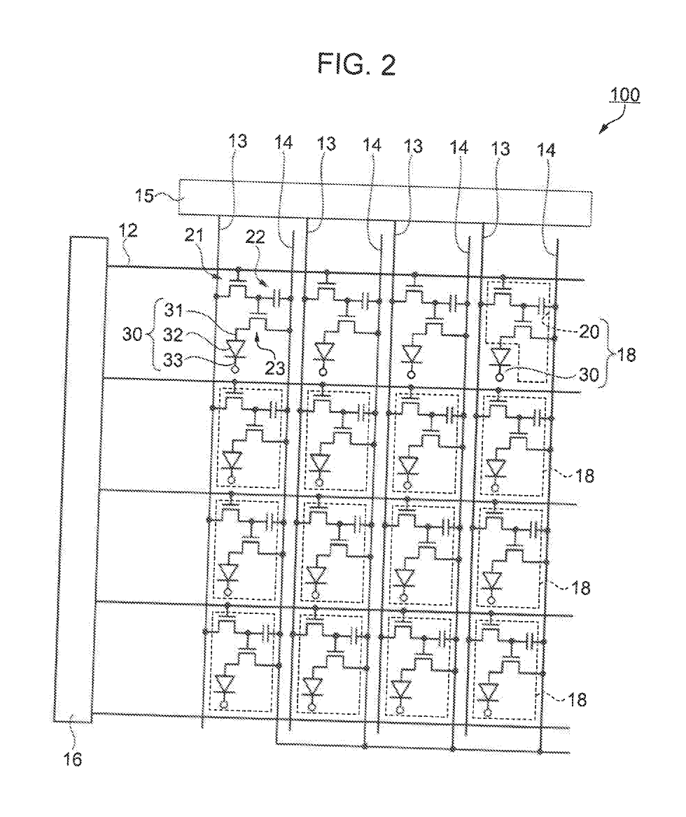

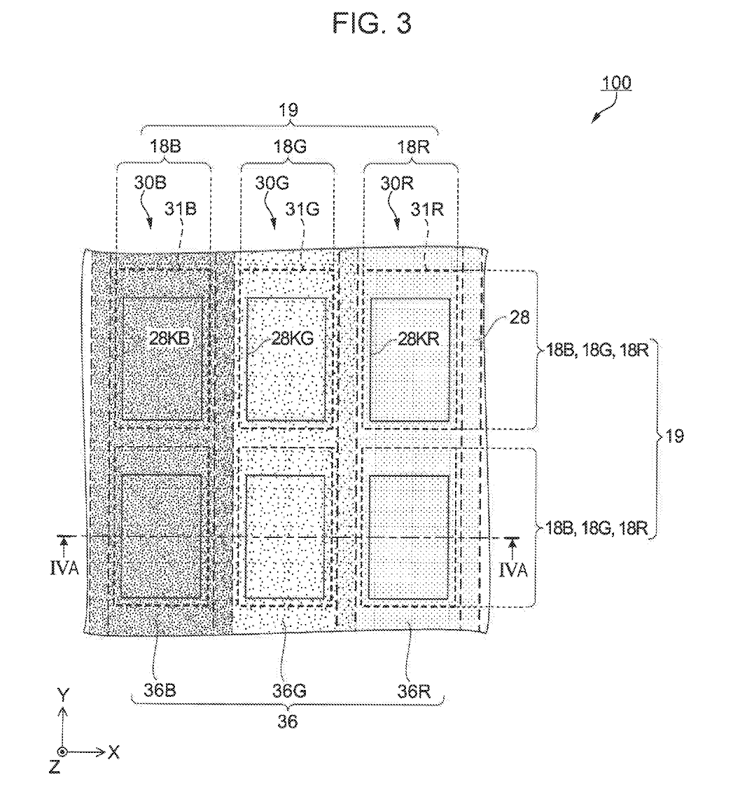

First, an organic EL device as an electro-optical device according to a first embodiment will be described with reference to FIG. 1 to FIG. 3. FIG. 1 is a schematic plan view illustrating a configuration of the organic EL device according to the first embodiment. FIG. 2 is an equivalent circuit diagram illustrating an electrical configuration of the organic EL device according to the first embodiment. FIG. 3 is a schematic plan view illustrating disposition of the organic EL element and a color filter in a sub pixel. An organic EL device 100 according to the present embodiment is a self-luminous type microdisplay appropriate to a display unit of a head mount display (HMD) to be described below.

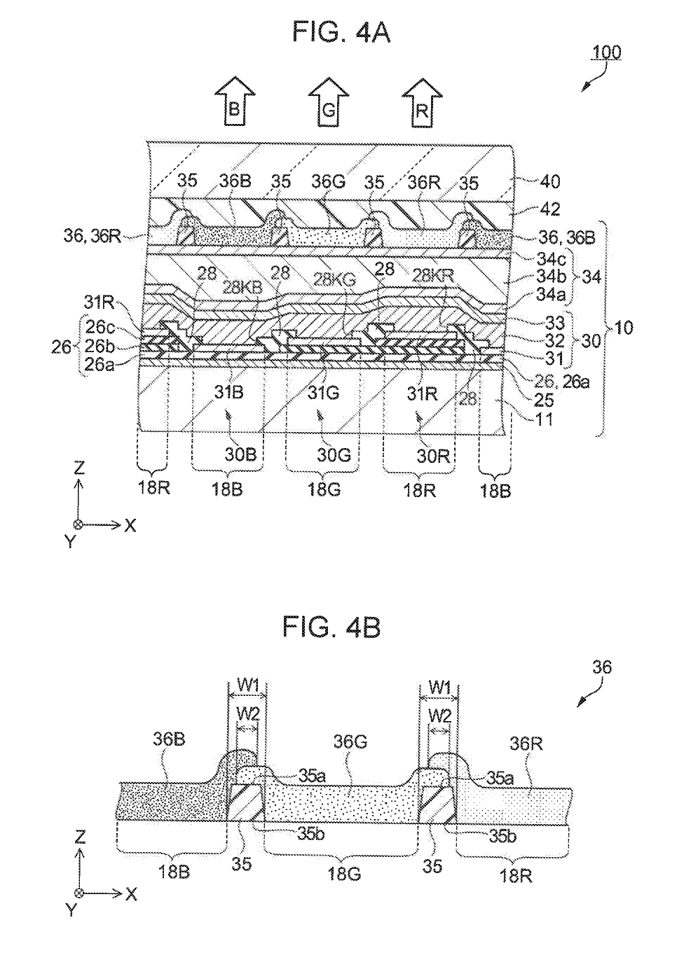

As shown in FIG. 1, the organic EL device 100 according to the preset embodiment includes an element substrate 10 and a protective substrate 40. Both substrates are disposed to face each other and adhered through a filler 42 (see FIG. 4A).

The element substrate 10 includes a display area E and a non-display area F surrounding the display area E. In the display area E, a sub pixel 18B from which blue (B) light is emitted as a first pixel, a sub pixel 18G from which green (G) light is emitted as a second pixel, and a sub pixel 18R from which red (R) light is emitted are arranged, for example, in a matrix shape. In the organic EL device 100, as a pixel 19 including the sub pixel 18B, the sub pixel 18G, and the sub pixel 18R is a display unit, a full-color display is provided.

Furthermore, in following descriptions, the sub pixel 18B, the sub pixel 18G, and the sub pixel 18R are collectively referred to as a sub pixel 18. The display area E is an area through which light emitted from the sub pixel 18 passes and is the area for light being displayed. The non-display area F is an area through which light emitted from the sub pixel 18 does not pass and which does not contribute to display.

Since the element substrate 10 is larger than the protective substrate 40, a plurality of external connection terminals 103 are arranged along with a first side of the element substrate 10 protruding from the protective substrate 40. A data line driving circuit 15 is provided between the plurality of external connection terminals 103 and the display area E. A scanning line driving circuit 16 is provided between a second side and a third side of the element substrate 10 which are opposite to each other and perpendicular to the first side, and the display area E.

Since the protective substrate 40 is smaller than the element substrate 10, the external connection terminals 103 are disposed to be exposed. The protective substrate 40 is a light transmissive substrate and is made of, for example, a quartz substrate, or a glass substrate, or the like. The protective substrate 40 has a role for protecting the organic EL element 30 such that the organic EL element 30 (see FIG. 2) which is disposed in the sub pixel 18 and described below is not damaged in the display area E, and is disposed at least to face the display area E. In the organic EL device 100 according to the present embodiment, light emitted from the sub pixel 18 is obtained from the protective substrate 40 side and a top emission system is employed.

In the following descriptions, a direction along with the first side in which the external connection terminals 103 is arranged is referred to an X direction and a direction along with the other two sides (the second side, the third side) which are opposite to each other and perpendicular to the first side is referred to a Y direction. A direction facing the protective substrate 40 from the element substrate 10 is referred to a Z direction. Also, viewing along with the Z direction from the protective substrate 40 is referred to as “plan view”.

In the display area E according to the present embodiment, disposition where the sub pixels 18 from which luminescence of the same color is obtained are arranged in a column direction (Y direction) and the sub pixels 18 from which luminescence of different color is obtained are disposed in a row direction (X direction), that is, so-called, stripe type disposition of the sub pixel 18 is employed. The sub pixel 18 includes the organic EL element 30 and a color filter 36 (see FIG. 3 or FIG. 4A). Configurations of the organic EL element 30 and the color filter 36 will be described in detail.

Furthermore, FIG. 1 shows the disposition of the sub pixels 18B, 18G, and 18R in the display area E, but the disposition of the sub pixel 18 in the row direction (X direction) in this order of B, G, and R is not limited thereto. For example, the sub pixel 18 may be disposed in this order of G, B, and R. Also, the disposition of the sub pixel 18 is not limited to the stripe type and may be a delta type, a bayer type, and a S stripe type. In addition, shapes and sizes of the sub pixels 18B, 18G, and 18R are not limited to be the same.

### Electrical Configuration of Electro-Optical Device

As shown in FIG. 2, the organic EL device 100 includes a scanning line 12 and a data line 13 intersecting with each other, and a power supply line 14 intersecting with the scanning line 12. The scanning line 12 is electrically connected to the scanning line driving circuit 16 and the data line 13 is electrically connected to the data line driving circuit 15. Also, the sub pixel 18 is disposed in an area which is demarcated by the scanning line 12 and the data line 13.

The sub pixel 18 includes the organic EL element 30 and a pixel circuit 20 for controlling a drive of the organic EL element 30. Hereinafter, as a first organic EL element, the organic EL element 30 disposed in the sub pixel 18B is referred to as an organic EL element 30B, as a second organic EL element, the organic EL element 30 disposed in the sub pixel 18G is referred to as an organic EL element 30G, and the organic EL element 30 disposed in the sub pixel 18R is referred to as an organic EL element 30R.

The organic EL element 30 is configured to have a pixel electrode 31, a luminescence functional layer 32, and an opposite electrode 33. The pixel electrode 31 functions as an anode which injects an electron hole into the luminescence functional layer 32. The opposite electrode 33 functions as a cathode which injects an electron into the luminescence functional layer 32. In the luminescence functional layer 32, exciton (state of the electron and the electron hole which are attracted to each other by the electrostatic Coulomb force) is formed by the injected electron hole and electron, then, when exciton disappears (when the electron and the electron hole are recombined), a part of energy is emitted as fluorescence and phosphorescence. In the present embodiment, the luminescence functional layer 32 is formed so as to obtain white luminescence from the luminescence functional layer 32.

The pixel circuit 20 includes a switching transistor 21, a storage capacity 22, and a driving transistor 23. The two transistors 21 and 23 can be configured to have, for example, a n-channel type transistor or a p-channel type transistor.

A gate of the switching transistor 21 is electrically connected to the scanning line 12. A source of the switching transistor 21 is electrically connected to the data line 13. A drain of the switching transistor 21 is electrically connected to a gate of the driving transistor 23.

A drain of the driving transistor 23 is electrically connected to the pixel electrode 31 of the organic EL element 30. A source of the driving transistor 23 is electrically connected to the power supply line 14. The storage capacity 22 is electrically connected between the gate of the driving transistor 23 and the power supply line 14.

When the scanning line 12 is driven by a control signal provided by the scanning line driving circuit 16 and a state of the switching transistor 21 becomes an ON state, potential is held in the storage capacity 22 through the switching transistor 21 based on a image signal provided by the data line 13. An ON or OFF state of the driving transistor 23 is determined in accordance with the potential of the storage capacity 22, that is, gate potential of the driving transistor 23. Then, when the driving transistor 23 becomes the ON state, current corresponding to the amount of the gate potential flows from the power supply line 14 to the organic EL element 30 through the driving transistor 23. The organic EL element 30 emits light at luminance corresponding to the amount of current flowing through the luminescence functional layer 32.

Furthermore, the configuration of the pixel circuit 20 is not limited to have two transistors 21 and 23, and the pixel circuit 20 may be configured to have an additional transistor for control of current flowing through the organic EL element 30.

### Disposition of Pixel Electrode and Color Filter

Next, disposition of the pixel electrode 31 and the color filter 36 of the organic EL element 30 in the sub pixel 18 will be described with reference to FIG. 3.

As shown in FIG. 3, the pixel electrodes 31 of the organic EL element 30 are respectively disposed in a plurality of the sub pixels 18 disposed in the matrix shape in the X and Y directions. Specifically, the pixel electrode 31B of the organic EL element 30B is disposed in the sub pixel 18B, the pixel electrode 31G of the organic EL element 30G is disposed in the sub pixel 18G, and the pixel electrode 31R of the organic EL element 30R is disposed in the sub pixel 18R. When seen in a plan view, each of the pixel electrodes 31 (31B, 31G, and 31R) is approximately a rectangular shape and a longitudinal direction thereof is disposed along the Y direction.

In this configuration of the organic EL device 100, the three sub pixels 18B, 18G, and 18R which are arranged in the X direction are displayed as one pixel 19. A disposition pitch of the pixel 19 in the X direction is, for example, equal to or less than 10 μm.

An insulation film 28 is formed to cover an outer edge of each of the pixel electrodes 31B, 31G, and 31R. In the insulation film 28, opening portions 28KB, 28KG, and 28KR of the approximately rectangular shapes in the plan view are formed on the pixel electrodes 31B, 31G, and 31R. Each of the pixel electrodes 31B, 31G, and 31R is exposed inside the opening portions 28KB, 28KG, and 28KR. Furthermore, the shapes of the opening portions 28KB, 28KG, and 28KR are not limited to the substantially rectangular and may be, for example, a track shape whose short side is arcuate.

The color filter 36 is disposed in the sub pixels 18B, 18G, and 18R. The color filter 36 is configured to have a coloring layer 36B of blue color (B) as a first coloring layer, a coloring layer 36G of green color (G) as a second coloring layer, and a coloring layer 36R of red color (R). Specifically, the coloring layer 36B is disposed with respect to a plurality of the sub pixels 18B arranged in the Y direction, the coloring layer 36G is disposed with respect to a plurality of the sub pixels 18G arranged in the Y direction, and the coloring layer 36R is disposed with respect to a plurality of the sub pixels 18R arranged in the Y direction.

That is, the coloring layer 36B is disposed in the stripe shape extending in the Y direction so as to overlap the pixel electrode 31B (opening portion 28KB) arranged in the Y direction. The coloring layer 36G is disposed in the stripe shape extending in the Y direction so as to overlap the pixel electrode 31G (opening portion 28KG) arranged in the Y direction. Similarly, the coloring layer 36R is extended in the Y direction and disposed in the stripe shape so as to overlap the pixel electrode 31R (opening portion 28KR) arranged in the Y direction.

In the present embodiment, the coloring layer 36B and the coloring layer 36G are disposed to overlap each other between the sub pixel 18B and the sub pixel 18G adjacent to each other in the X direction. The coloring layer 36G and the coloring layer 36R are disposed to overlap each other between the sub pixel 18G and the sub pixel 18R adjacent to each other in the X direction. Also, although not shown in the drawings, the coloring layer 36R and the coloring layer 36B are disposed to overlap each other between the sub pixel 18R and the sub pixel 18B adjacent to each other in the X direction.

### Structure of Sub Pixel

Next, a structure of the sub pixel 18 in the organic EL device 100 will be described with reference to FIG. 4A and FIG. 4B. FIG. 4A is a schematic cross-sectional view illustrating a configuration of the sub pixel taken along line IVA-IVA in FIG. 3. FIG. 4B is a schematic cross-sectional view illustrating the enlarged color filter in FIG. 4A.

As shown in FIG. 4A, the organic EL device 100 includes the element substrate 10 and the protective substrate 40 which are disposed so as to face each other through the filler 42. The filler 42 may be configured by, for example, epoxy resin and acrylic resin having light transmission properties, or the like for bonding the element substrate 10 and the protective substrate 40.

The element substrate 10 includes a substrate 11 as a substrate in the invention, a reflective layer 25, a light transmission layer 26, the organic EL element 30, a sealing part 34, and the color filter 36 which are sequentially stacked on the substrate 11 in the Z direction.

The substrate 11 is a semiconductor substrate, for example, silicon or the like. The scanning line 12, the data line 13, the power supply line 14, the data line driving circuit 15, the scanning line driving circuit 16, the pixel circuit 20 (the switching transistor 21, the storage capacity 22, and the driving transistor 23), and the like described above are formed in the substrate 11 using known techniques (see FIG. 2). In FIG. 4A, a wiring and a circuit configuration thereof are not illustrated.

Furthermore, the substrate 11 is not limited to the semiconductor substrate such as silicon and may be a substrate such as quartz or glass. In other words, a transistor constituting the pixel circuit 20 may be a MOS type transistor having an active layer on the semiconductor substrate and may be a thin film transistor or a field effect transistor formed on the substrate such as quartz or glass.

The reflective layer 25 is disposed throughout the sub pixels 18B, 18G, and 18R, and light generated from each of the organic EL elements 30B, 30G, and 30R of the sub pixels 18B, 18G, and 18R is reflected by the reflective layer 25. As a material for forming the reflective layer 25, it is preferable to use aluminum or silver or the like which can realize high reflectance.

The light transmission layer 26 is provided on the reflective layer 25. The light transmission layer 26 is configured to have a first insulation film 26a, a second insulation film 26b, and a third insulation film 26c. The first insulation film 26a is disposed throughout the sub pixels 18B, 18G, and 18R on the reflective layer 25. The second insulation film 26b is stacked on the first insulation film 26a and is disposed throughout the sub pixels 18G and 18R. The third insulation film 26c is stacked on the second insulation film 26b and is disposed in the sub pixel 18R.

That is, the light transmission layer 26 of the sub pixel 18B is configured to have the first insulation film 26a, the light transmission layer 26 of the sub pixel 18G is configured to have the first insulation film 26a and the second insulation film 26b, and the light transmission layer 26 of the sub pixel 18R is configured to have the first insulation film 26a, the second insulation film 26b, and the third insulation film 26c. Thus, a film thickness of the light transmission layer 26 is larger in this order of the sub pixel 18B, the sub pixel 18G, and the sub pixel 18R.

The organic EL element 30 is provided on the light transmission layer 26. The organic EL element 30 includes the pixel electrode 31, the luminescence functional layer 32, and the opposite electrode 33 which are sequentially stacked in the Z direction. The pixel electrode 31 is formed of a transparent conductive film, for example, indium tin oxide (ITO) film and is formed in an island shape for each of the sub pixels 18.

The insulation film 28 is disposed to cover a periphery of each of the pixel electrodes 31B, 31G, and 31R. As described above, in the insulation film 28, the opening portion 28KB is formed on the pixel electrode 31B, the opening portion 28KG is formed on the pixel electrode 31G, and the opening portion 28KR is formed on the pixel electrode 31R. The insulation film 28 is made of, for example, silicon oxide or the like.

In parts in which the opening portions 28KB, 28KG, and 28KR are provided, the pixel electrode 31 (31B, 31G, and 31R) is contacted to the luminescence functional layer 32 and the electron hole is supplied from the pixel electrode 31 to the luminescence functional layer 32, thus, the luminescence functional layer 32 emits light. That is, the areas in which the opening portions 28KB, 28KG, and 28KR are provided are luminescence areas in which the luminescence functional layer 32 emits light. In an area in which the insulation film 28 is provided, supplying of the electron hole from the pixel electrode 31 to the luminescence functional layer 32 is controlled, thus, luminescence of the luminescence functional layer 32 is controlled. That is, the areas in which the insulation film 28 is provided are the luminescence areas in which luminescence of the luminescence functional layer 32 is controlled.

The luminescence functional layer 32 is disposed throughout the sub pixels 18B, 18G, and 18R and to cover all of the display area E (see FIG. 1). The luminescence functional layer 32 includes, for example, an electron hole injection layer, an electron hole transport layer, an organic luminescent layer, an electron transport layer, and the like which are sequentially stacked in the Z direction. The organic luminescence layer emits light with a wavelength within a range from blue color to red color. The organic luminescence layer may be configured to have one layer or a plurality of layers including, for example, a blue color luminescence layer, a green color luminescence layer, and a red color luminescence layer, or the blue color luminescence layer and a yellow color luminescence layer in which luminescence with the wavelength within the range of red color (R) or green color (G) is obtained.

The opposite electrode 33 is disposed so as to cover the luminescence functional layer 32. The opposite electrode 33 is made of, for example, alloy of magnesium and silver and the like, and a film thickness thereof is controlled so as to have light transmission properties and photoreflectance.

The sealing part 34 covering the opposite electrode 33 is configured to have a first sealing layer 34a, a planarization layer 34b, and a second sealing layer 34c which are sequentially stacked in the Z direction. The first sealing layer 34a and the second sealing layer 34c are formed using an inorganic material. The inorganic material through which moisture and oxygen and the like hardly passes is, for example, silicon oxide, silicon nitride, silicon oxynitride, aluminum oxide, or the like.

Examples of a method for forming the first sealing layer 34a and the second sealing layer 34c include a vacuum deposition method, an ion plating method, a sputtering method, a CVD method, or the like. It is desirable to employ the vacuum deposition method or the ion plating method in that the organic EL element 30 can not be damaged by a heat or the like. Film thicknesses of the first sealing layer 34a and the second sealing layer 34c are, for example, approximately 50 nm to 1000 nm, and more preferably 200 nm to 400 nm such that a crack or the like is less likely to occur during a film formation and light transmission properties is obtained.

The planarization layer 34b has the light transmission properties and can be formed by using, for example, heat or any of the resin material of ultraviolet curable epoxy resin, acrylic resin, urethane resin, silicone resin. Also, the planarization layer 34b may be formed by using a coating type inorganic material (silicon oxide or the like). The planarization layer 34b is formed to be stacked on the first sealing layer 34a covering a plurality of the organic EL elements 30.

The planarization layer 34b covers a defect (pinhole, crack) or a foreign substance to form a substantially flat surface during a film formation of the first sealing layer 34a. Since an unevenness is occurred on the surface of the first sealing layer 34a due to an influence of the light transmission layer 26 of which a film thickness is different from the first sealing layer 34a, it is preferable that the film thickness of the planarization layer 34b be, for example, approximately 1 μm to 5 μm in order to alleviate the unevenness. Thereby, the color filter 36 formed on the sealing part 34 is less likely to be affected by the unevenness.

A light transmissive convex portion 35 is provided between the sub pixels 18 which are adjacent to each other on the sealing part 34. The convex portion 35 is formed by a photolithography method using a photosensitive resin material having no coloring material. The convex portion 35 is disposed in the stripe shape (streak) extending in the Y direction on the sealing part 34 so as to distinguish each of the coloring layers 36B, 36G, and 36R of the color filter 36 formed on the convex portion 35. An upper surface portion 35a is formed on the protective substrate 40 (in the +Z direction) side of the convex portion 35 and a lower surface portion 35b is formed on the sealing part 34 (in the −Z direction) side of the convex portion 35 (see FIG. 4B). The cross sectional shape of the convex portion 35 may be, for example, a trapezoidal shape, and a rectangular shape or the like.

Furthermore, the convex portion 35 is not limited to be disposed in the stripe shape and may be disposed in a cross stripes shape extending in X direction and Y direction so as to surround the opening portions 28KB, 28KG, and 28KR in the pixel electrode 31 of each of the sub pixels 18. A height of the convex portion 35 is preferably lower (smaller) than an average film thickness of the coloring layers 36B, 36G, and 36R described below.

The color filter 36 is formed on the sealing part 34. The color filter 36 is configured to have the coloring layers 36B, 36G, and 36R which formed by the photolithography method using a photosensitive resin material having coloring material of blue (B), green (G), and red (R). That is, main materials of the convex portion 35 and the coloring layers 36B, 36G, and 36R are the same. The coloring layers 36B, 36G, and 36R are formed in response to the sub pixels 18B, 18G, and 18R.

The coloring layers 36B, 36G, and 36R are respectively formed to fill a portion between the convex portions 35 adjacent to each other and to cover at least a part of the convex portion 35, on the sealing part 34. Among the coloring layers 36B, 36G, and 36R, the coloring layers adjacent to each other are formed so that parts of the coloring layers overlap each other.

For example, the coloring layer 36B adjacent to the coloring layer 36G is in contact with a side wall of the convex portion 35 and an edge of the coloring layer 36B overlaps an edge of the coloring layer 36G covering the upper surface portion 35a of the convex portion 35. Similarly, the coloring layer 36R adjacent to the coloring layer 36G is in contact with the a side wall of the convex portion 35 and an edge of the coloring layer 36R overlaps an edge of the coloring layer 36G covering the upper surface portion 35a the convex portion 35.

Although not shown in the drawings, a method of formation of the convex portion 35 and the coloring layers 36B, 36G, and 36R will be described in brief. A photosensitive resin layer is formed by coating and pre-baking a photosensitive resin material having no coloring material on the sealing part 34 using a spin coating method as the method of the formation of the convex portion 35. The photosensitive resin material may be a negative type or a positive type. The convex portion 35 is formed on the sealing part 34 by exposing and developing the photosensitive resin layer using the photolithography method.

Subsequently, the coloring layers 36B, 36G, and 36R are formed on the sealing part 34 on which the convex portion 35 is formed. After a photosensitive resin layer is formed by applying a photosensitive resin material having a coloring material of each color using a spin coating method in the same manner as the convex portion 35, the coloring layers 36B, 36G, and 36R are formed by exposing and developing the photosensitive resin layer using the photolithography method. In the present embodiment, the coloring layers 36G, 36B, and 36R are formed in this order of the coloring layers 36G, 36B, and 36R.

As a result, the edge of the −X direction side of the coloring layer 36G formed on the sub pixel 18G covers at least a part of the upper surface portion 35a of the convex portion 35 disposed between the sub pixel 18G and the sub pixel 18B, and the edge of the +X direction side of the coloring layer 36G covers at least a part of the upper surface portion 35a of the convex portion 35 disposed between the sub pixel 18G and the sub pixel 18R. The edge of the −X direction side of the coloring layer 36B formed on the sub pixel 18B covers at least a part of the upper surface portion 35a of the convex portion 35 disposed between the sub pixel 18B and the sub pixel 18R, and the edge of the +X direction side of the coloring layer 36B covers the edge of the coloring layer 36G on the convex portion 35 disposed between the sub pixel 18B and the sub pixel 18G. The edge of the −X direction side of the coloring layer 36R formed on the sub pixel 18R covers the edge of the coloring layer 36G on the convex portion 35 disposed between the sub pixel 18R and the sub pixel 18G, and the edge of the +X direction side of the coloring layer 36R covers the edge of the coloring layer 36B on the convex portion 35 disposed between the sub pixel 18R and the sub pixel 18B.

In other words, in the upper surface portion 35a of the convex portion 35 disposed between the sub pixel 18B and the sub pixel 18G, the edge of the coloring layer 36G and the edge of the coloring layer 36B are disposed to overlap each other. In the upper surface portion 35a of the convex portion 35 disposed between the sub pixel 18G and the sub pixel 18R, the edge of the coloring layer 36G and the edge of the coloring layer 36R are disposed to overlap each other. Then, in the upper surface portion 35a of the convex portion 35 disposed between the sub pixel 18R and the sub pixel 18B, the edge of the coloring layer 36B and the edge of the coloring layer 36R are disposed to overlap each other.

Furthermore, it is preferable that the edges of both sides of the coloring layers 36G, 36B, and 36R do not cross the upper surface portion 35a of the convex portion 35, that is, the edges of both sides of the coloring layers 36G, 36B, and 36R do not protrude from the upper surface portion 35a of the convex portion 35 to the adjacent sub pixel side when seen in the plan view.

In FIG. 4B, a cross section of the color filter 36 including the sub pixel 18G and parts of the sub pixels 18B and 18R disposed on both sides of the sub pixel 18G is shown. A width (length in the X direction) of the lower surface portion 35b of the convex portion 35 is W1 and a width (length in the X direction) of the part in which the adjacent coloring layers overlap each other in the upper surface portion 35a of the convex portion 35 is W2. It is preferable that the width W2 of the part in which the coloring layers overlap each other be 15% to 75% of the width W1 of the lower surface portion 35b of the convex portion 35. The reason for this will be described below.

### Optical Resonance Structure

Next, returning to FIG. 4A, the optical resonance structure included in the organic EL device 100 according to the embodiment will be described. The organic EL device 100 according to the present embodiment includes an optical resonance structure between the reflective layer 25 and the opposite electrode 33. In the organic EL device 100, light generated from the luminescence functional layer 32 is repeatedly reflected between the reflective layer 25 and the opposite electrode 33, an intensity of the light with a specified wavelength (resonant wavelength) in response to an optical distance between the reflective layer 25 and the opposite electrode 33 is amplified, and the light is emitted from the protective substrate 40 in the Z direction as light for a display.

In the present embodiment, the light transmission layer 26 functions as an adjuster for the optical distance between the reflective layer 25 and the opposite electrode 33. As described above, the film thickness of the light transmission layer 26 is larger in this order of the sub pixel 18B, the sub pixel 18G, and the sub pixel 18R. As a result, the optical distance between the reflective layer 25 and the opposite electrode 33 is larger in this order of the sub pixel 18B, the sub pixel 18G, and the sub pixel 18R.

Furthermore, the optical distance can be expressed by a sum of products of a refractive index and a film thickness of each of the layers between the reflective layer 25 and the opposite electrode 33. The optical distance between the reflective layer 25 and the opposite electrode 33 may be adjusted by varying the film thicknesses of the pixel electrode 31 (31B, 31G, and 31R) from each other instead of the light transmission layer 26.

A film thickness of the light transmission layer 26 is set in the sub pixel 18B such that the resonant wavelength (peak wavelength when luminance is maximum) is 465 nm to 475 nm which is a first wavelength range. The film thickness of the light transmission layer 26 is set in the sub pixel 18G such that the peak wavelength is 520 nm to 550 nm which is a second wavelength range. The film thickness of the light transmission layer 26 is set in the sub pixel 18R from which light of red color (R) is generated such that the peak wavelength is 610 nm to 650 nm.

As a result, blue color light (B) with a peak wavelength range of 465 nm to 475 nm is emitted from the sub pixel 18B, green color light (G) with a peak wavelength range of 520 nm to 550 nm is emitted from the sub pixel 18G, and red color light (R) with a peak wavelength range of 610 nm to 650 nm is emitted from the sub pixel 18R.

In other words, the organic EL device 100 includes the optical resonance structure in which the intensity of light with the specified wavelength is amplified, obtains a blue color light component from white light emitted from the luminescence functional layer 32 in the sub pixel 18B, obtains a green color light component from white light emitted from the luminescence functional layer 32 in the sub pixel 18G, and obtains a red color light component from white light emitted from the luminescence functional layer 32 in the sub pixel 18R.

As described above, in a case where the organic EL element 30 includes the optical resonant structure, light generated from the organic EL element 30 is light emitted from the opposite electrode 33 to the sealing part 34 side, and is light with spectrum different from spectrum of light generated inside the luminescence functional layer 32.

The color filter 36 is disposed on the sealing part 34 in the sub pixels 18B, 18G, and 18R. Light within the peak wavelength range obtained from each of the sub pixels 18 by the optical resonance structure passes through the coloring layers 36G, 36B, and 36R of the color filter 36, thereby the coloring layers 36G, 36B, and 36R have a function for increasing the color purity of each of light of blue color (B), green color (G), and red color (R) emitted to the protective substrate 40 side.

Also, light generated from the organic EL element 30B of the sub pixel 18B passes through the coloring layer 36B of blue color and is shielded by the coloring layer 36G of green color or the coloring layer 36R of red color. Similarly, light generated from the organic EL element 30G of the sub pixel 18G passes through the coloring layer 36G of green color and is shielded by the coloring layer 36B of blue color or the coloring layer 36R of red color. Light generated from the organic EL element 30R of the sub pixel 18R passes through the coloring layer 36R of red color and is shielded by the coloring layer 36B of blue color or the coloring layer 36G of green color. Thus, a direction of light obtained from the organic EL device 100 is defined according to a position of each of the organic EL elements 30 and a position of each of the coloring layers of the color filter 36.

### Viewing Angle Characteristics

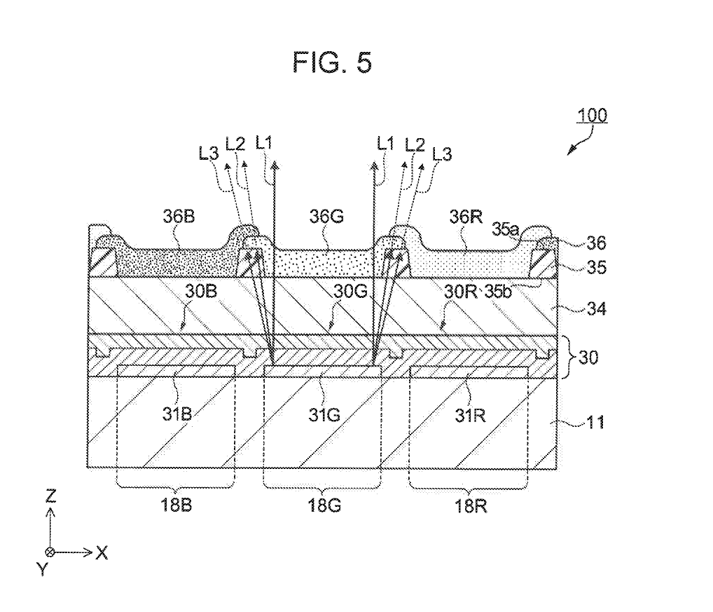

Next, viewing angle characteristics in the organic EL device 100 according to the first embodiment will be described with a comparative example. FIG. 5 is a diagram illustrating the viewing angle characteristics of the organic EL device according to the first embodiment. Also, FIG. 12 is a diagram illustrating viewing angle characteristics of an organic EL device according to the comparative example.

An organic EL device 200 according to the comparative example as shown in FIG. 12 includes the optical resonance structure and the same configuration except that the configuration of the color filter 37 differs from that of the organic EL device 100 according the present embodiment. The color filter 37 according to the comparative example is configured to have coloring layers 37B, 37G, and 37R corresponding to the sub pixels 18B, 18G, and 18R. The coloring layers adjacent to each other are formed in contact with each other in the upper surface portion 35a of the convex portion 35 between the sub pixels 18 adjacent to each other.

Here, the sub pixel 18G will be described as an example. Light L1 generated from the organic EL element 30G in the sub pixel 18G in a perpendicular direction (Z direction) passes through the coloring layer 37G and is emitted to the protective substrate 40 (see FIG. 4A) side. Oblique light L2 generated from the organic EL element 30G in an oblique direction inclined to the sub pixel 18B side or 18R side adjacent to the sub pixel 18G with respect to the perpendicular direction passes through the convex portion 35 and the coloring layer 37G and is emitted to the protective substrate 40 side. Oblique light L3 generated from the organic EL element 30G in the oblique direction further inclined to the sub pixel 18B side or 18R side adjacent to the sub pixel 18G with respect to the perpendicular direction passes through the convex portion 35 and the coloring layer 37B or the convex portion 35 and the coloring layer 37R and is emitted to the protective substrate 40 side.

In the organic EL device 200 having the optical resonance structure, since an optical distance of the oblique light L2 generated from the organic EL element 30G of the sub pixel 18G in the oblique direction becomes larger than that of the light L1 generated in the perpendicular direction, the peak wavelength is shifted to a short wavelength side (blue color light side) from an originally intended peak wavelength. Therefore, although the oblique light L2 passes through the coloring layer 37G in the same manner as the light L1, the oblique light L2 has a color different from the light L1 and color purity of green color light emitted to the protective substrate 40 side is decreased.

Also, since the optical distance of the oblique light L3 generated from the organic EL element 30G in the oblique direction further inclined than the oblique light L2 becomes larger than that of the light L1, the peak wavelength is further shifted to the short wavelength side (blue color light side) from the originally intended peak wavelength. Therefore, the oblique light L3 generated from the organic EL element 30G to the sub pixel 18R side passes through the coloring layer 37B at a higher rate as compared with the light L1 and the oblique light L2, and color mixture occurs between the sub pixel 18G and the sub pixel 18B.

Also, in the sub pixels 18B and 18R, the color purity of light emitted to the protective substrate 40 side is decreased by the oblique light L2 and L3 passing through and the color mixture occurs between the sub pixels 18 adjacent to each other, in the same manner as the sub pixel 18G. In this way, if the color purity is decreased and the color mixture occurs when the oblique light L2 and L3 pass between the sub pixels 18 to be visible from the oblique direction, there is a problem that a viewing angle at which a full-color display of which a display unit is the pixel 19 configured to have sub pixels 18B, 18G, and 18R can be visible within an originally intended color range is narrowed.

As shown in FIG. 5, in the organic EL device 100 according to the present embodiment, the coloring layers adjacent to each other are disposed to overlap each other in the upper surface portion 35a of the convex portion 35 disposed between the sub pixels 18 adjacent to each other. Thus, the oblique light L2 generated from the organic EL element 30G inclined to the sub pixel 18B side or 18R side adjacent to the sub pixel 18G with respect to the perpendicular direction passes through the coloring layer 36B or the coloring layer 36R in addition to the convex portion 35 and the coloring layer 36G. Therefore, the amount of transmission of the oblique light L2 is suppressed to be small by the coloring layer 36B or the coloring layer 36R as compared with the organic EL device 200 according to the comparative example.

Also, the oblique light L3 generated from the organic EL element 30G further inclined to the sub pixel 18B side or 18R side adjacent to the sub pixel 18G with respect to the perpendicular direction passes through the coloring layer 36B or the coloring layer 36R in addition to the convex portion 35 and the coloring layer 36G. Therefore, the amount of transmission of the oblique light L3 is suppressed to be small as compared with the organic EL device 200 according to the comparative example. As a result, the color purity of light emitted from each of the sub pixel 18 is increased and the color mixture is suppressed between the sub pixels 18, and thereby the viewing angle at which the full-color display of which a display unit is the pixel 19 can be visible within the originally intended color range becomes wider.

Here, if the width of the part in which the adjacent two coloring layers overlap each other in the upper surface portion 35a of the convex portion 35 is small, the oblique light L2 and L3 passing between the sub pixels 18 adjacent to each other are likely to pass through only one coloring layer, and thereby it is difficult to obtain an effect that the amount of transmission the oblique light L2 and L3 is suppressed. On the other hand, if the edge of the coloring layer crosses the upper surface portion 35a of the convex portion 35 and enters an area of the adjacent sub pixel 18, the amount of transmission of light generated from the adjacent sub pixel 18 with the originally intended peak wavelength is reduced. Thus, as shown in FIG. 4B, it is preferable that the width W2 of the part in which the adjacent coloring layers are overlapped each other in the upper surface portion 35a of the convex portion 35 be 15% to 75% of the width W1 of the lower surface portion 35b of the convex portion 35.

### Spectrum Characteristics of Color Filter

Next, spectrum characteristics of the color filter according to the first embodiment will be described. In the configuration of the present embodiment, it is desirable that the coloring layers 36B, 36G, and 36R constituting the color filter 36 have predetermined transmission characteristics and predetermined cut-off characteristics for color light generated from each of the sub pixels 18 to increase the effects that the color purity of the color light emitted from each of the sub pixel 18 is increased and the color mixture between the sub pixels 18 is reduced.

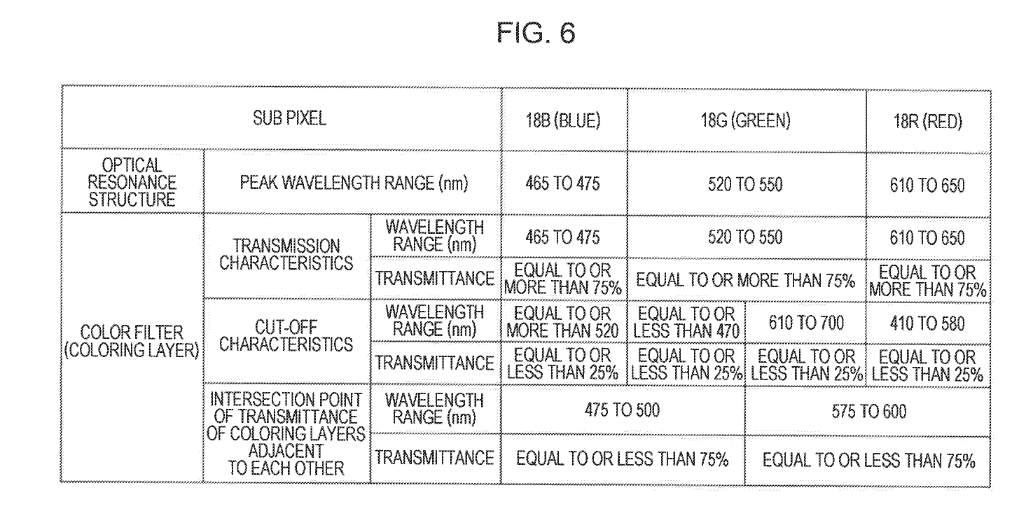

FIG. 6 is a table illustrating the spectrum characteristics of the color filter according to the first embodiment. FIG. 6 shows the peak wavelength range of each of the sub pixels 18 in the optical resonance structure, and the transmission characteristics and cut-off characteristics with respect to a specific wavelength range of the color filter 36 (the coloring layers 36G, 36B, and 36R). As described above, in the present embodiment, the peak wavelength range of each of the sub pixels 18 according to the optical resonance structure is set to 465 nm to 475 nm for the sub pixel 18B, is set to 520 nm to 550 nm for the sub pixel 18G, and is set to 610 nm to 650 nm for the sub pixel 18R.

As shown in FIG. 6, the coloring layer 36B disposed in the sub pixel 18B has transmittance of equal to or more than 75% with respect to light with a wavelength of 465 nm to 475 nm which is the peak wavelength range of light generated from the sub pixel 18B. Then, the coloring layer 36B has the transmittance of equal to or less than 25% with respect to light with a wavelength equal to or more than 520 nm as a predetermined wavelength of a longer wavelength side (green color light side) than the peak wavelength range of light generated from the sub pixel 18B.

The coloring layer 36G disposed in the sub pixel 18G has transmittance of equal to or more than 75% with respect to light with a wavelength of 520 nm to 550 nm which is the peak wavelength range of light generated from the sub pixel 18G. Then, the coloring layer 36G has the transmittance of equal to or less than 25% with respect to light with a wavelength equal to or less than 470 nm as a predetermined wavelength of the short wavelength side (blue color light side) than the peak wavelength range of light generated from the sub pixel 18G and light with the wavelength of 610 nm to 700 nm as the predetermined wavelength of the longer wavelength side (red color light side) than the peak wavelength range.

The coloring layer 36R disposed in the sub pixel 18R has transmittance of equal to or more than 75% with respect to light with a wavelength of 610 nm to 650 nm which is the peak wavelength range of light generated from the sub pixel 18R. Then, the coloring layer 36R has the transmittance of equal to or less than 25% with respect to light with a wavelength of 410 nm to 580 nm as the predetermined wavelength of the short wavelength side (green color light side) than the peak wavelength range of light generated from the sub pixel 18R.

Also, it is preferable that an intersection point of transmittance of each of the coloring layer 36B and the coloring layer 36G adjacent to each other be within a wavelength range of 475 nm to 500 nm and the coloring layer 36B and the coloring layer 36G have transmittance of equal to or less than 75% with respect to light with a wavelength at the intersection point. Then, it is preferable that an intersection point of transmittance of each of the coloring layer 36G and the coloring layer 36R adjacent to each other be within a wavelength range of 575 nm to 600 nm and the coloring layer 36G and the coloring layer 36R have transmittance of equal to or less than 75% with respect to light with a wavelength at the intersection point.

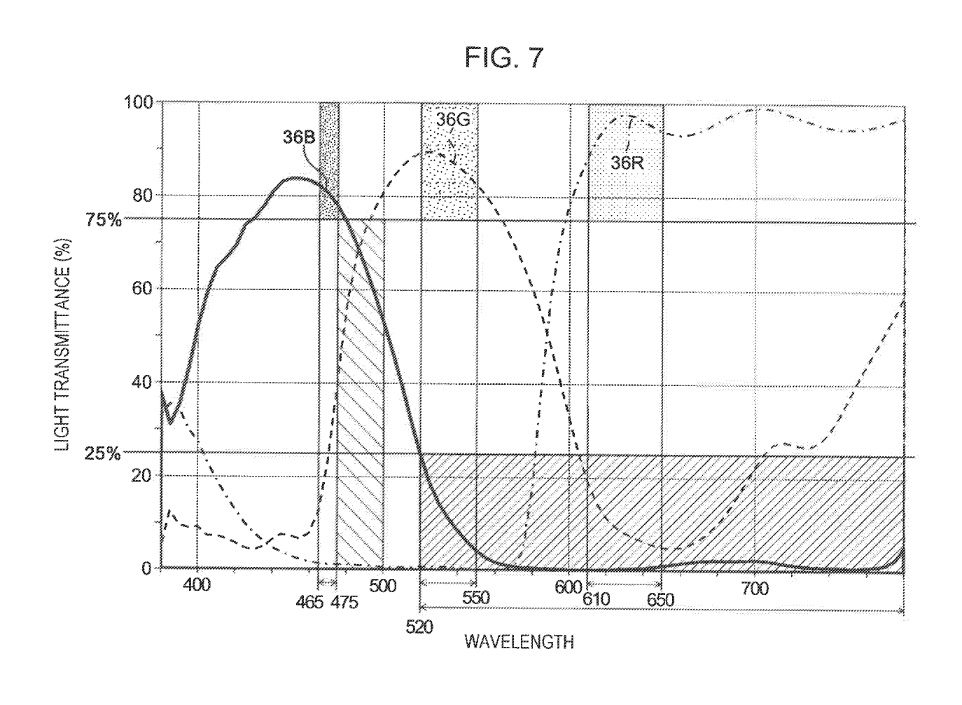

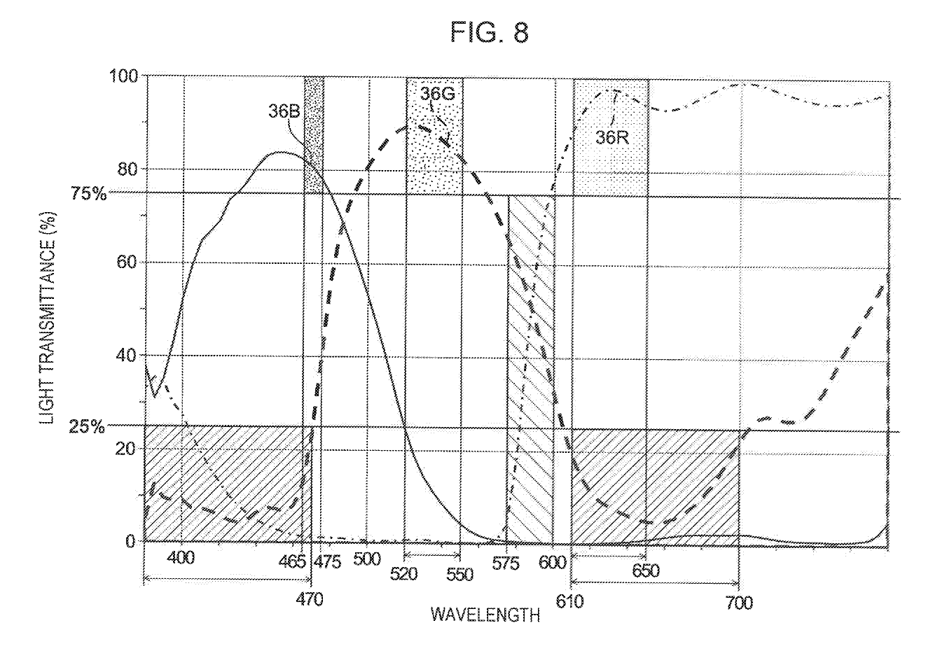

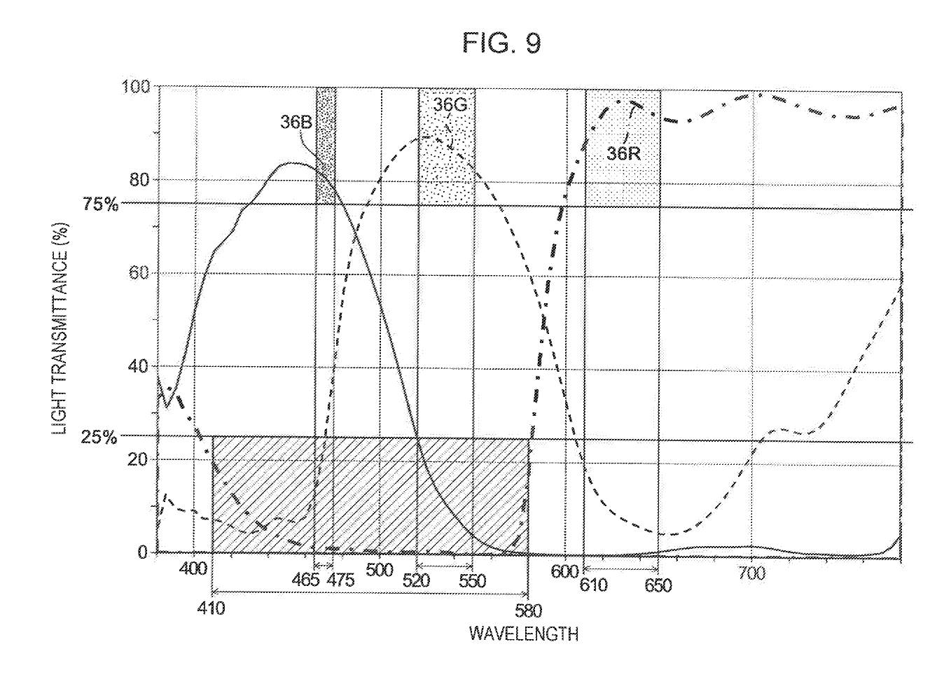

The spectrum characteristics of the color filter 36 will be further described with reference to FIG. 7, FIG. 8, and FIG. 9. FIG. 7, FIG. 8, and FIG. 9 are diagrams illustrating examples of the spectrum characteristics of the color filter. In detail, FIG. 7 is a graph illustrating one example of the spectrum characteristics of a blue coloring layer. FIG. 8 is a graph illustrating one example of the spectrum characteristics of a green coloring layer. FIG. 9 is a graph illustrating one example of the spectrum characteristics of a red coloring layer.

As one example of the color filter 36, FIG. 7, FIG. 8, and FIG. 9 show the graph of the spectrum characteristics of the coloring layer 36B disposed in the sub pixel 18B in a solid line, the graph of the spectrum characteristics of the coloring layer 36G disposed in the sub pixel 18G in a dashed line, and the graph of the spectrum characteristics of the coloring layer 36R disposed in the sub pixel 18R in a one dot chain line. Also, the peak wavelength ranges of light generated from each of the sub pixels 18B, 18G, and 18R are denoted by dots.

As shown by the solid line in FIG. 7, since the coloring layer 36B has transmittance of equal to or more than 75% with respect to blue color light with the peak wavelength range of 465 nm to 475 nm generated from the sub pixel 18B, the amount of transmission of the blue color light within the peak wavelength range can be increased. On the other hand, as shown by denoting oblique lines in a lower left direction in FIG. 7, since the coloring layer 36B has transmittance of equal to or less than 25% with respect to light with the wavelength equal to or more than 520 nm including the peak wavelength range of 520 nm to 550 nm generated from the sub pixel 18G and the peak wavelength range of 610 nm to 650 nm generated from the sub pixel 18R, the amount of transmission of light with a wavelength other than that of the blue color light including green color light and red color light can be decreased.

Accordingly, the color purity of the blue color light (light L1) passing through the coloring layer 36B from the sub pixel 18B and emitted to the protective substrate 40 side is increased. Then, the oblique light L2 and L3 shifted to the short wavelength side from the peak wavelength of the red color light generated from the sub pixel 18R disposed to be adjacent to the sub pixel 18B can be effectively shielded by the coloring layer 36B (the amount of transmission can be reduced).

Also, as shown by denoting oblique lines in a lower right direction in FIG. 7, the intersection point of transmittance of the coloring layer 36B and transmittance of the coloring layer 36G adjacent to the coloring layer 36B is within the wavelength range of 475 nm to 500 nm between the blue color light and the green color light and the transmittance at the intersection point is equal to or less than 75%. Thus, the oblique light L2 and L3 shifted to the short wavelength side (blue color light side) from the peak wavelength of the green color light generated from the sub pixel 18G disposed to be adjacent to the sub pixel 18B can be effectively shielded by the coloring layer 36B and the coloring layer 36G (the amount of transmission can be reduced).

As shown by the dashed line in FIG. 8, since the coloring layer 36G has transmittance of equal to or more than 75% with respect to the green color light with the peak wavelength range of 520 nm to 550 nm generated from the sub pixel 18G, the amount of transmission of the green color light within the peak wavelength range can be increased. On the other hand, as shown by denoting oblique lines in the lower left direction, since the coloring layer 36G has transmittance of equal to or less than 25% with respect to light with the wavelength equal to or less than 470 nm and light with the wavelength range of 610 nm to 700 nm, the amount of transmission of light with a wavelength other than that of the green color light can be decreased.

Accordingly, the color purity of the green color light (light L1) passing through the coloring layer 36G from the sub pixel 18G and emitted is increased. Then, the oblique light L2 and L3 shifted to the short wavelength side from the peak wavelength of the blue color light generated from the sub pixel 18B disposed to be adjacent to the sub pixel 18G can be effectively shielded by the coloring layer 36G (the amount of transmission can be reduced).

Also, as shown by denoting oblique lines in the lower right direction in FIG. 8, the intersection point of transmittance of the coloring layer 36G and transmittance of the coloring layer 36R adjacent to the coloring layer 36G is within the wavelength range of 575 nm to 600 nm between the green color light and the red color light and the transmittance at the intersection point is equal to or less than 75%. Thus, the oblique light L2 and L3 shifted to the short wavelength side (green color light side) from the peak wavelength of the red color light generated from the sub pixel 18R can be effectively shielded by the coloring layer 36G and the coloring layer 36R (the amount of transmission can be reduced).

As shown by the one dot chain line in FIG. 9, since the coloring layer 36R has transmittance of equal to or more than 75% with respect to the red color light with the peak wavelength range of 610 nm to 650 nm generated from the sub pixel 18R, the amount of transmission of the red color light within the peak wavelength range can be increased. On the other hand, as shown by denoting oblique lines in the lower left direction, since the coloring layer 36R has transmittance of equal to or less than 25% with respect to light with the wavelength range of 410 nm to 580 nm, the amount of transmission of light with wavelengths other than that of the red color light can be decreased.

Accordingly, the color purity of the red color light (light L1) passing through the coloring layer 36R from the sub pixel 18R and emitted is increased. Then, the oblique light L2 and L3 shifted to the short wavelength side from the peak wavelength of the green color light generated from the sub pixel 18G disposed to be adjacent to the sub pixel 18R and the oblique light L2 and L3 shifted to the short wavelength side from the peak wavelength of the blue color light generated from the sub pixel 18B disposed to be adjacent to the sub pixel 18R can be effectively shielded by the coloring layer 36R (the amount of transmission can be reduced).

Furthermore, there is a case where the light L1 and L2 are shifted to a long wavelength side from the originally intended peak wavelength by planar disposition or a film thickness or the like in a boundary portion of the sub pixel 18 of a configuration element formed between the reflective layer 25 and the opposite electrode 33. Even in such a case, the light L1 and L2 shifted to a long wavelength side can be effectively shielded by the two coloring layers adjacent to each other according to the spectrum characteristics of the color filter 36 of the first embodiment.

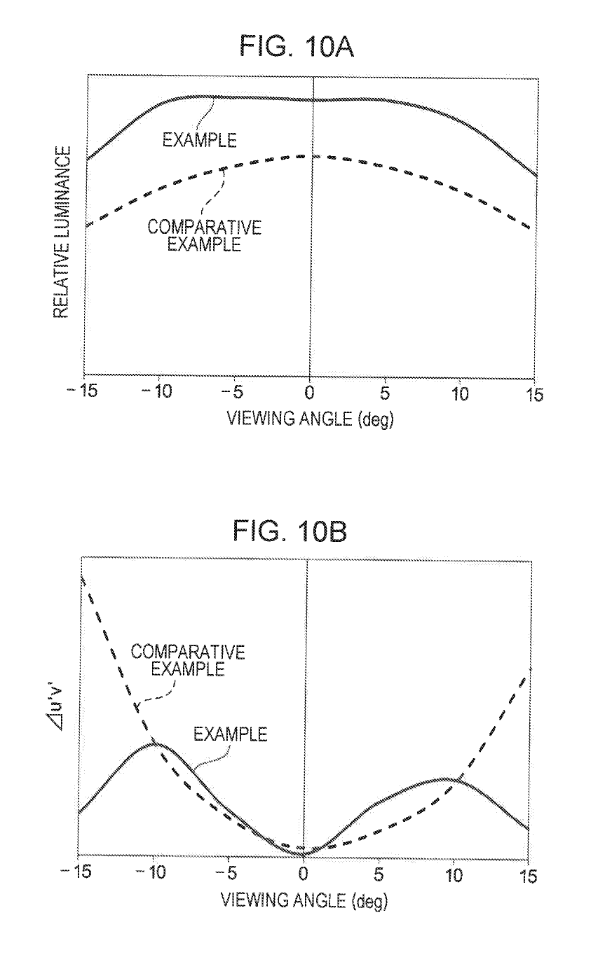

Subsequently, the example including the color filter 36 having the spectrum characteristics described above and the comparative example not having the spectrum characteristics described above for the viewing angle characteristics of the organic EL device 100 will be described by comparing with each other. FIG. 10A and FIG. 10B are diagrams illustrating the viewing angle characteristics of the example. In detail, FIG. 10A is a graph illustrating the viewing angle characteristics according to a relative luminance by comparing the example and the comparative example. FIG. 10B is a graph illustrating the viewing angle characteristics according to a chromaticity change by comparing the example and the comparative example.

The example of the organic EL device 100 includes the color filter 36 (the coloring layers 36G, 36B, and 36R) having the predetermined transmission characteristics (transmittance of equal to or more than 75% with respect to light with the peak wavelength range) and the predetermined cut-off characteristics (transmittance of equal to or less than 25% with respect to light with the predetermined wavelength) shown in FIG. 6. The comparative example has the same configuration as the example except that the comparative example includes a color filter having the transmission characteristics of approximately 70% with respect to light with the peak wavelength range and the cut-off characteristics of approximately 25% to 30% with respect to light with the predetermined wavelength. Here, the viewing angle characteristics in the sub pixel 18R of the red color are compared between the example and the comparative example.

The relative luminance is digitized and graphed in FIG. 10A and the chromaticity change (Δu′v′) is digitized and graphed in FIG. 10B using an optical simulator in the range of ±15° in the X direction with respect to the perpendicular based on a reference when seeing the sub pixel 18R from the perpendicular direction (0°). FIG. 10A and FIG. 10B show the example in the solid line and show the comparative example in the dashed line. Furthermore, the chromaticity change (Δu′v′) shows a chromaticity change in an u′v′ chromaticity diagram which is uniform chromaticity space (CIE 1976 UCS chromaticity diagram).

As shown in FIG. 10A, since the transmittance with respect to light with the peak wavelength range in the example is higher as compared with the comparative example, the relative luminance of the example is higher than the relative luminance of the comparative example in all the range of 0°±15°. The relative luminance of the comparative example is approximately 80% of the relative luminance of the example in the perpendicular direction (0°). Also, while the relative luminance is decreased according to the angle changing up to 0°±15° in the comparative example, the relative luminance is not practically changed in the range of 0°±100 and is rapidly decreased beyond the range of 0°±100 in the example, as compared with the comparative example. This is because the oblique light beyond the range of 0°±10° emitted from the sub pixel 18R is cut well by the coloring layers 36B and 36G of the sub pixels 18B and 18G adjacent to the sub pixel 18R.

As shown in FIG. 10B, although the chromaticity change (Δu′v′) is not practically changed within the range of the viewing angle of 0°±10° in the example and the comparative example, the chromaticity change of the comparative example is increased beyond the range of 0°±10° as compared with the example. Also, while the chromaticity change within the range of −100 to −15° is not practically different from the chromaticity change of the range of 10° to 15° in the example, the chromaticity change within the range of −10° to −15° is greater than the chromaticity change within the range of 10° to 15° and symmetry properties of the chromaticity change of the comparative example is less than the example. Since the oblique light beyond the range of 0°±10° emitted from the sub pixel 18R is cut well by the coloring layers 36B and 36G of the sub pixels 18B and 18G adjacent to the sub pixel 18R in the example, the chromaticity change within the range of 0°±15° is suppressed to be smaller than that of the comparative example.

In this way, in the example which includes the color filter 36 having the predetermined transmission characteristics (transmittance of equal to or more than 75% with respect to light with the peak wavelength range) and the predetermined cut-off characteristics (transmittance of equal to or less than 25% with respect to light with the predetermined wavelength), the relative luminance can be increased and the chromaticity change can be suppressed to be small in a wider range of the viewing angle. Thus, the color display with high quality can be obtained in the wide viewing angle.

As described above, in the configuration of the organic EL device 100 according to the first embodiment, following effects can be obtained.

(1) The convex portion 35 having the light transmission properties is formed between the sub pixels 18B, 18G, and 18R in which the coloring layers 36B, 36G, and 36R are formed, and the coloring layers adjacent to each other are disposed to overlap each other in the upper surface portion 35a of the convex portion 35. Therefore, for example, in the sub pixel 18B, the oblique light L2 and L3 generated from the organic EL element 30B and emitted to between the sub pixel 18B and the sub pixel 18G pass through both of the coloring layer 36B and the coloring layer 36G after passing through the convex portion 35. Thus, the amount of transmission of the oblique light L2 and L3 emitted from the organic EL element 30B to between the sub pixel 18B and the sub pixel 18G is suppressed as compared with a case where the oblique light L2 and L3 pass through only one of the coloring layer 36B and the coloring layer 36G. Accordingly, since the color mixture is less likely to occur between the sub pixels 18B, 18G, and 18R, the organic EL device 100 obtaining the color display with high quality in the more wide viewing angle can be provided.

(2) In the coloring layer 36B, 36G, and 36R disposed in each of the sub pixels 18B, 18G, and 18R, for example, the coloring layer 36B disposed in the sub pixel 18B transmits light with the wavelength range of 465 nm to 475 nm generated from the organic EL element 30B by equal to or more than 75% but, transmits light with the wavelength equal to or more than 520 nm of the longer wavelength side than that of the light only by equal to or less than 25%. Also, the coloring layer 36G disposed in the sub pixel 18G transmits light with the wavelength range of 520 nm to 550 nm generated from the organic EL element 30G by equal to or more than 75%, but, transmits light with the wavelength equal to or less than 470 nm of the short wavelength side than that of the light only by equal to or less 25%. Therefore, the color purity of the blue color light and the green color light emitted from each of the sub pixel 18B and the sub pixel 18G is increased. Also, since the amount of transmission of the oblique light L2 and L3 emitted from the organic EL element 30B to between the sub pixel 18B and the sub pixel 18G is suppressed by the coloring layer 36G and the amount of transmission of the oblique light L2 and L3 emitted from the organic EL element 30G to between the sub pixel 18B and the sub pixel 18G is suppressed by the coloring layer 36B, the color mixture is suppressed between the sub pixel 18B and the sub pixel 18G. Accordingly, the organic EL device 100 obtaining the color display with high quality in the wide color range and in the wide viewing angle can be provided.

(3) In the coloring layers 36B, 36G, and 36R disposed in each of the sub pixels 18B, 18G, and 18R, for example, since the width W2 of the part in which the coloring layer 36B and the coloring layer 36G overlap each other is equal to or more than 15% of the width W1 of the lower surface portion 35b of the convex portion 35, each of the oblique light L2 and L3 emitted from the organic EL element 30B or the organic EL element 30G to between the sub pixel 18B and the sub pixel 18G is likely to pass through both of the coloring layer 36B and the coloring layer 36G. Also, since the width W2 of the part in which the coloring layer 36B and the coloring layer 36G adjacent to each other overlap each other is equal to or less than 75% of the width W1 of the lower surface portion 35b of the convex portion 35, the coloring layer 36B is prevented from protruding to the adjacent sub pixel 18G and the coloring layer 36G is prevented from protruding to the adjacent sub pixel 18B.

### Second Embodiment

### Electronic Apparatus

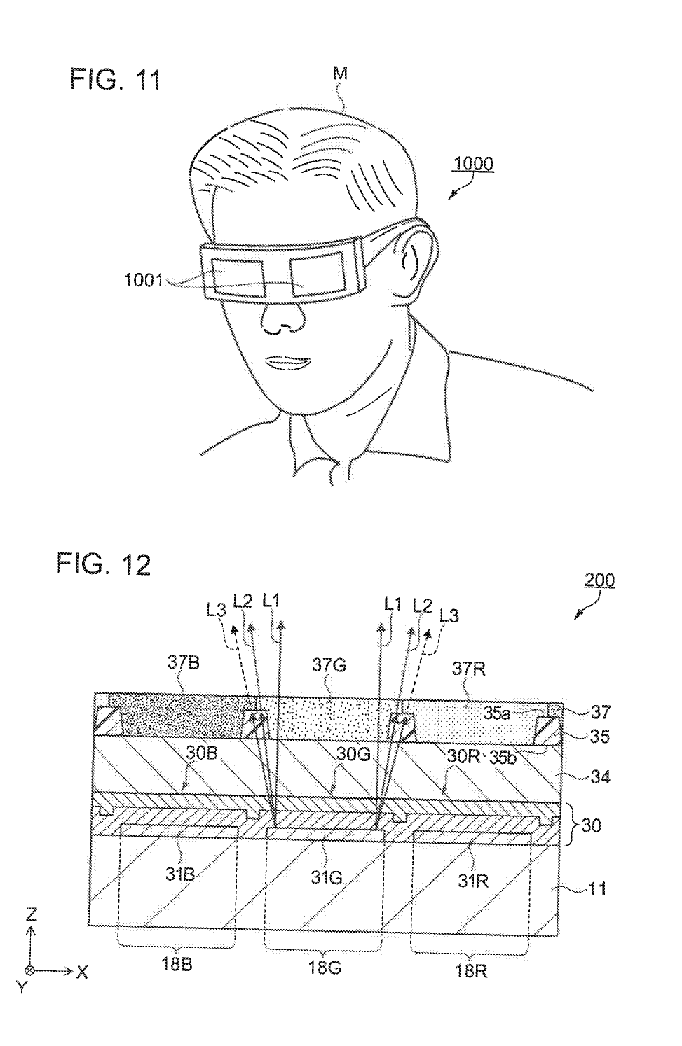

Next, an electronic apparatus according to a second embodiment will be described with reference to FIG. 11. FIG. 11 is a schematic view illustrating a configuration of a head mount display as the electronic apparatus according to the second embodiment.

As shown in FIG. 11, a head mount display (HMD) 1000 according to the second embodiment includes two display units 1001 provided corresponding to right and left eyes. An observer M can see characters and images which are displayed on the display unit 1001 by mounting the head mount display 1000 on a head as glasses. For example, when images in consideration of binocular parallax are displayed on the right and left display units 1001, the observer can see and enjoy stereoscopic images.

The organic EL device 100 according to the first embodiment is mounted on the display unit 1001. Thus, it can be possible to provide the small and lightweight head mount display 1000 having the excellent display quality in the viewing angle characteristics, particularly high color purity and the head mount display 1000 is suitable for a head mount display of a see-through type.

The configuration of the head mount display 1000 is not limited to have the two display units 1001, may have the one display unit 1001 corresponding to either the right or left.

Furthermore, the electronic apparatus on which the organic EL device 100 according to the first embodiment is mounted is not limited to the head mount display 1000. The electronic apparatus on which the organic EL device 100 is mounted is, for example, the electronic apparatus having the display unit such as a personal computer, a portable information terminal, a navigator, a viewer, a head-up display, and the like.

Embodiments described above merely show one embodiment of the invention and can be arbitrarily modified and applied within the scope of the invention. As modification examples, for example, the following or the like can be considered.

### Modification Example

The luminescence element provided on the display area E in the organic EL device 100 according to the first embodiment is not limited to the sub pixels 18B, 18G, and 18R corresponding to luminescence of blue (B), green (G), and red (R). For example, a sub pixel 18Y from which the luminescence of yellow (Y) other than above the three colors is obtained may be provided. Accordingly, it is possible to further improve color reproducibility. Also, the sub pixels 18 of the two colors among the above three colors may be provided.

The entire disclosure of Japanese Patent Application No. 2016-026414, filed Feb. 15, 2016 is expressly incorporated by reference herein.

What is claimed is:

1. An electro-optical device comprising:
a substrate;
a first organic EL element that is formed in a first pixel on the substrate;
a second organic EL element that is formed in a second pixel adjacent to the first pixel on the substrate;
a sealing part that is formed to cover the first organic EL element and the second organic EL element;
a first coloring layer that is formed in the first pixel on the sealing part;
a second coloring layer that is formed in the second pixel on the sealing part; and
a convex portion that has light transmission properties and is formed between the first pixel and the second pixel on the sealing part,
wherein the first coloring layer and the second coloring layer are disposed to overlap each other at an upper surface portion of the convex portion.

2. The electro-optical device according to claim 1,
wherein light emitted from the first organic EL element to the sealing part side is within a first wavelength range,
light emitted from the second organic EL element to the sealing part side is within a second wavelength range different from the first wavelength range,
the first coloring layer has transmittance of equal to or more than 75% with respect to light within the first wavelength range and transmittance of equal to or less than 25% with respect to light with a predetermined wavelength which is closer to the second wavelength range side than to the first wavelength range, and
the second coloring layer has transmittance of equal to or more than 75% with respect to light within the second wavelength range and transmittance of equal to or less than 25% with respect to light with a predetermined wavelength which is closer to the first wavelength range side than to the second wavelength range.

3. The electro-optical device according to claim 1,
wherein a width of a part in which the first coloring layer and the second coloring layer are disposed to overlap each other in the upper surface portion of the convex portion is 15% to 75% of a width of a lower surface portion of the convex portion.

4. The electro-optical device according to claim 1,
wherein the first coloring layer and the second coloring layer are disposed to cover at least a part of the upper surface portion of the convex portion.

5. An electronic apparatus comprising:
the electro-optical device according to claim 1.

6. An electronic apparatus comprising:
the electro-optical device according to claim 2.

7. An electronic apparatus comprising:
the electro-optical device according to claim 3.

8. An electronic apparatus comprising:
the electro-optical device according to claim 4.
